(19) United States
(12) Patent Application Publication
(10) Pub. No.: US 2004/0043611 A1
(43) Pub. Date: Mar. 4, 2004

(54) Method of reducing a defect level after chemically mechanically polishing a copper-containing substrate by rinsing the substrate with an oxidizing solution

(76) Inventors: Uwe Gunter Stoeckgen, Dresden (DE); Gerd Franz Christian Marxsen, Radebeul (DE)

Correspondence Address: J. Mike Amerson, Williams, Morgan & Amerson, P.C., Suite 1100, 10333 Richmond, Houston, TX, 77042, US

(21) Appl. No.: 10/360,221

(22) Filed: Feb. 6, 2003

(30) Foreign Application Priority Data
Aug. 30, 2002 (DE) 102 40 114.4

(51) Int. Cl. H01L 21/4763; H01L 21/44; H01L 21/302; H01L 21/461

(52) U.S. Cl. 438/687; 438/638; 438/633; 438/692

(57) ABSTRACT

In the chemical mechanical polishing of copper-containing substrates, a rinse treatment is carried out with an oxidizing agent, such as hydrogen peroxide, so as to substantially completely oxidize and, thus, passivate exposed copper surface areas. Moreover, by using the oxidizing agent, organic additives required for efficient polishing performance may be effectively removed.

### BACKGROUND OF THE INVENTION

1. Field of the Present Invention

Generally, the present invention relates to the fabrication of microstructures, such as integrated circuits, and, more particularly, to the chemical mechanical polishing of copper-containing material layers, such as metallization layers, in highly sophisticated integrated circuits.

2. Description of the Prior Art

In manufacturing microstructures, such as integrated circuits, various material layers are deposited on a substrate and are patterned by photolithography, etching, ion implantation and the like to provide a huge number of individual features, such as circuit elements in the form of transistors, capacitors, resistors and the like. Due to the ever decreasing feature sizes of the individual structure elements, sophisticated photolithography and etch techniques have been developed that allow the resolution of critical dimensions, i.e., of minimum feature sizes, well beyond the wavelength of the radiation used for transferring images from a mask layer onto the substrate. Since these sophisticated imaging techniques are quite sensitive to any underlying material layers and to the surface topography, it is frequently necessary to planarize the substrate so as to provide a substantially planar surface for the application of further material layers to be patterned. This holds especially true for so-called metallization layers required in integrated circuits to electrically connect the individual circuit elements. Depending on the feature sizes of the circuit elements and the number thereof, typically a plurality of metallization layers that was stacked on top of each other and electrically connected together by so-called vias are required for providing for the complex functionality of today's integrated circuits.

It has, therefore, become standard practice in forming stacked metallization layers to planarize the substrate surface prior to forming a subsequent metallization layer. Chemical mechanical polishing (CMP) has proven to be a viable process technique for this purpose. In chemically mechanically polishing a substrate, in addition to the mechanical removal of the material, a slurry is supplied typically containing one or more chemical reagents that chemically react with the material or materials, wherein the reaction products may be more efficiently removed by the mechanical polishing. Moreover, the relative motion between the substrate and a polishing pad, as well as the force with which the substrate is pressed against the polishing pad, and the composition of the slurry, are controlled to obtain the desired removal rate.

Recently, chemical mechanical polishing has increasingly gained in importance as aluminum is steadily replaced with copper in high end integrated circuits exhibiting feature sizes in the deep sub-micron regime. For minimum features sizes of 0.25 μm and less, the operational speed of the integrated circuits is no longer limited by the switching speed of the individual transistor elements but is mainly determined by the so-called interconnect delay, i.e., by the RC time constant caused by the parasitic capacitances between adjacent interconnect lines and the corresponding high resistances of these metal lines.

An increasing number of the individual circuit elements per unit area requires the number of interconnect lines to increase even more rapidly, while the dimensions of the individual lines, i.e., the cross-sectional area thereof, are decreased. An increased number of interconnect lines with decreased cross-sectional area, however, means a higher parasitic capacitance between adjacent lines in combination with an increased resistance of these lines. Therefore, semiconductor manufacturers increasingly employ copper as the metallization line, possibly in combination with a low-k material as a dielectric, to reduce the parasitic RC time constants due to copper's superior characteristics in comparison to aluminum in terms of electric conductivity and resistance against electromigration.

In addition to the many problems involved in processing copper in a semiconductor facility, it turns out that copper may not be very efficiently deposited in large amounts with well-established deposition techniques, such as chemical vapor deposition and sputter deposition. Moreover, copper may not be efficiently patterned by conventional anisotropic etch techniques. Therefore, instead of applying copper as a blanket layer and patterning metal lines, the so-called damascene method has become a standard process technique. In the damascene technique, trenches and vias are formed in a dielectric layer and subsequently the metal, i.e., the copper, is filled into the trenches and vias, wherein a certain amount of over-filling has to be provided so as to reliably fill the trenches and vias. Prior to depositing the copper, usually by a plating process, such as electroplating or electroless plating, a barrier layer has to be provided to minimize out-diffusion of copper into the adjacent dielectric. Thereafter, a thin copper seed layer is usually applied using sputter deposition to promote the subsequent plating process. After the deposition of the bulk copper, the excess metal, including the thin barrier layer and the seed layer, has to be reliably removed in order to obtain copper trenches and vias that are electrically insulated from each other. The excess material is removed by chemical mechanical polishing, requiring the abrasion of the bulk copper in a first polishing period and the removal of copper, the barrier material, and, to a certain amount, the dielectric during the final phase of the polishing process. Typically, the polishing process is carried out in at least two steps requiring a different chemistry in the slurries, as well as different parameter settings for speed of the relative motion and/or down force applied to the substrate during these different polishing steps.

Typically, abrasives are added to the slurry for the first step of the CMP process, so as to obtain a desired high removal rate for the bulk copper, whereas, in the final step, the removal step is more complex as typically two or more materials have to be polished at the same time, i.e., copper, the barrier material and the dielectric. In case of a standard dielectric, such as silicon dioxide, the dielectric and, typically, the barrier material are significantly harder than the copper so that copper is removed more rapidly than the other materials. Moreover, a certain amount of “over-polish” has to be applied to ensure the complete removal of any conductive material on surface portions of the dielectric material so as to minimize leakage currents between adjacent lines. Completely removing the conductive material all over a substrate having a diameter of 200 mm or, in future generations of 300 mm, is, however, a challenging task and necessarily leads to a certain amount of dishing and erosion of the metallization structure as will be shown in more detail in FIG. 1.

FIG. 1 schematically shows a cross-sectional view of a portion of a typical damascene structure 100. The structure 100 includes a substrate 101 that may include circuit elements (not shown) and possibly one or more metallization layers (not shown). On the substrate 101, a dielectric layer 102 is formed, for example comprised of silicon dioxide and/or silicon nitride, and the like. A plurality of narrow trenches 105 and a wide trench 103 connected to a via 104 are formed in the dielectric layer 102. The trenches 105, 103 and the via 104 are covered by a barrier layer 106, for example comprised of tantalum nitride, and are filled with copper. The structure 100 may be formed by well-established photolithography and etch techniques in combination with sputter deposition and electroplating as previously explained. Moreover, the structure 100 is shown after removing the excess material by chemical mechanical polishing. As noted above, during the final phase of the polishing process, a certain amount of over-polish has to be provided to reliably remove any conductive material outside the trenches 105 and 103. This leads, however, to an increased loss of copper in the trenches 105 and especially in the wide trench 103, as indicated by 108, which is usually referred to as dishing. Furthermore, the polishing process is associated with a loss of dielectric, as indicated by 107, and usually referred to as erosion, wherein the degree of dishing and erosion also depends on the special pattern that is to be polished, as indicated by 109, so that the amount of erosion, i.e., the loss of dielectric, is higher between the narrow trenches 105 than for the residual dielectric portions.

Although a certain degree of dishing may be desirable in view of the electrical insulation between adjacent trenches, excessive dishing has to be avoided, since any undue copper loss in the trenches 103 and 105 leads to a decreased cross-sectional area and thus to a degraded conductivity during operation of the device. It has, therefore, become standard practice to add specific agents to the slurry to improve the polish uniformity, for example, by adding so-called inhibitors to prevent etching, i.e., the chemical reaction, at the trench 103 as long as neighboring copper regions having a higher height during removal of the bulk copper are polished. Thus, in addition to typical CMP defects, such as particles, the damascene structure 100 may comprise slurry residuals or precipitates, often in the form of organic compounds after completion of the CMP process.

Therefore, specific additives may be introduced into the slurry of the final step or may even be used in a final rinse treatment of the structure 100 in an attempt to remove these defects. However, additives in the form of organic compounds may still remain on the substrate and may cause delamination of further layers to be deposited on the damascene structure 100. A further issue in chemically mechanically polishing the structure 100 is the corrosion of copper, which may even be promoted by the additives introduced into the final slurry or a subsequent rinse treatment. Pitting corrosion represents, however, a severe reliability degradation, as the deposition of subsequent layers is degraded and the electrical characteristics of the copper lines are deteriorated.

In view of the problems explained above, it is, therefore, highly desirable to provide a process sequence that allows the avoidance of, or at least the reduction of, copper contamination with organic additives introduced in solutions used for treating the copper surface, as is, for example, the case in the chemical mechanical polishing.

### SUMMARY OF THE INVENTION

Generally, the present invention is directed to a method of reducing copper contamination by additives promoting corrosion and/or negatively affecting the formation of subsequent layers, wherein these additives are introduced during treating or rinsing the substrate, for example, during and after a chemical mechanical polishing process. To this end, prior to drying the substrate for further processing, a rinse treatment is carried out with an oxidizing agent so that organic contaminants may be removed, and the copper surface is oxidized in a consistent manner across the patterns and across the entire substrate. Accordingly, the employment of organic additives, such as corrosion inhibitors, surfactants and complexing agents, as presently considered necessary in sophisticated CMP processes, is still possible without unduly adversely affecting any subsequent processes. Thus, the defect rate may be significantly reduced, while the oxidized copper surface provides a more reliable basis for subsequent deposition processes, as the removal of a continuous oxide surface is a significantly more reliable and reproducible procedure than the removal of corroded surface portions.

According to one illustrative embodiment of the present invention, a method of planarizing a copper-containing surface formed on a substrate comprises chemically mechanically polishing the surface to remove excess copper and rinsing the substrate with an oxidizing agent to oxidize exposed copper areas.

According to a further illustrative embodiment of the present invention, a method of planarizing a metal-containing surface formed on a substrate comprises chemically mechanically polishing the surface to remove excess metal and carrying out a clean sequence after the polish process. The clean sequence includes a first step of rinsing the substrate and a last step of rinsing the substrate with an oxidizing agent to remove organic residuals while oxidizing exposed areas of the metal.

According to a further illustrative embodiment of the present invention, a method of minimizing corrosion of an exposed copper region after a wet surface treatment comprises wet-treating the substrate and rinsing the substrate with an oxidizing agent as a final wet-treating step.

### BRIEF DESCRIPTION OF THE DRAWINGS

The invention may be understood by reference to the following description taken in conjunction with the accompanying drawings, in which like reference numerals identify like elements, and in which:

FIG. 1 is a schematic cross-sectional view of a portion of a damascene structure after the completion of a prior art CMP process; and

FIG. 2 schematically depicts a CMP station in a simplified manner which is appropriate for carrying out the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

It should be noted that in the following illustrative embodiments of the present invention, a chemical mechanical polishing process is referred to as a typical example of a “wet” treatment of a metal-containing substrate, requiring the employment of organic additives to achieve an improved effect of the wet treatment. The principle of the present invention may, however, also be applied to any wet chemical etch techniques, and the like, that may be contemplated for processing copper-containing substrates.

FIG. 2 schematically shows, in a very simplified manner, a CMP station 200 that may be appropriate for carrying out the present invention. The CMP station 200 comprises three CMP units 210, 220 and 230 that may be operated separately from each other. Each of the CMP units 210, 220 and 230 comprises a polishing head 201 including an appropriate drive means. The polishing heads 201 are adapted to receive, hold in position, and convey a substrate 240 to be polished. Moreover, the CMP units 210, 220 and 230 each include a polishing platen with a polishing pad 202 provided thereon and a pad conditioner 203, as well as a liquid applicator 204 for applying a required fluid, such as a slurry, to the polishing pads 202. It should be noted that the CMP station 200 is quite complex and usually comprises various drive means for driving the polishing pads 202 relative to the polishing heads 201, as indicated by the corresponding arrows. Moreover, the polishing head 201 and the driving means associated therewith are configured to provide for substrate transportation from one CMP unit to another so that a substrate may be sequentially processed by the CMP stations 210, 220 and 230. Moreover, the polishing heads 201 are typically configured so as to allow the application of a specified downforce to a substrate attached thereto, or, in sophisticated CMP tools, the polishing heads 201 allow the exertion of different downforces at different substrate positions.

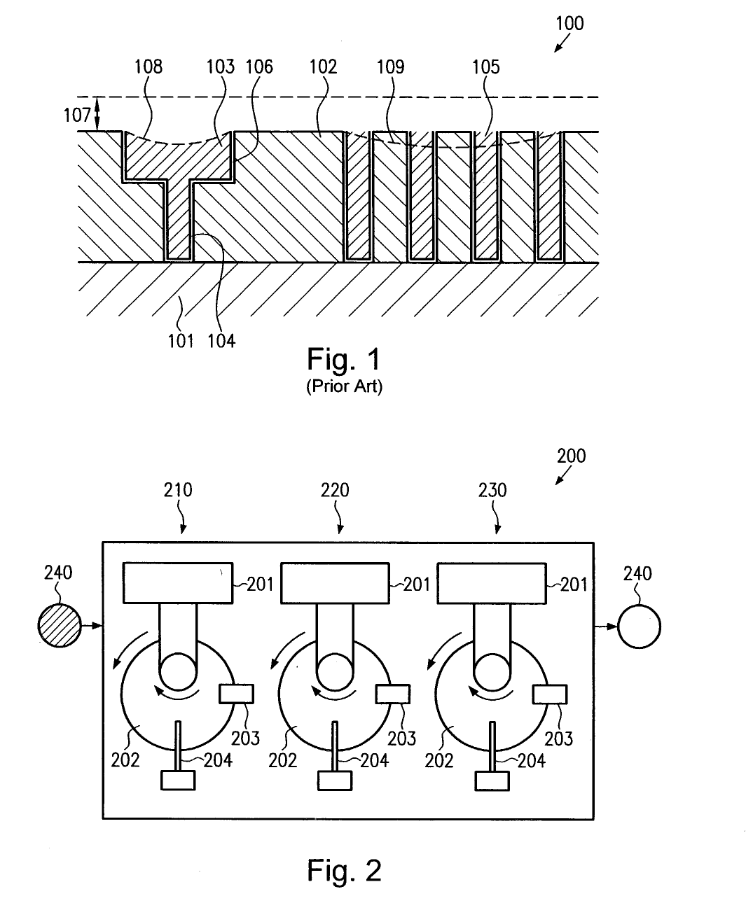

In operation, a substrate 240 including copper-containing surface portions that have to be polished, for example, a damascene structure as described with reference to FIG. 1, is supplied to the CMP unit 210. Process parameters, such as the speed of the relative motion between the polishing pad 202 and the polishing head 201, the applied downforce, the type of slurry supplied by the liquid applicator 204, polish time and the like, are adjusted in conformity with the specified process recipe. As previously noted, typically at least two polishing steps are carried out for removing excess material for a metallization layer, such as the damascene structure 100. After completion of the first phase of the CMP process, the substrate 240 is conveyed to the CMP unit 220 to be subjected to a further polishing step in accordance with the specified process recipe. If the step carried out on the process unit 220 is the last process in the polish sequence, typically the slurry composition is selected so as to minimize dishing of copper trenches, such as the trenches 105, 103, and to reduce corrosion of the exposed copper surfaces. As noted above, typically, one or more organic additives are introduced, which may not be completely removed in subsequent rinse treatments. Depending on the process recipe, the substrate 240 may be conveyed to the CMP station 230 for carrying out a rinse treatment to remove particles and/or additives from the substrate surface. Contrary to conventional process recipes, in one embodiment of the present invention, a rinse treatment is carried out in the CMP station 230, wherein at least at a final phase of the rinse treatment an oxidizing agent is supplied by the liquid applicator 204 so that, in addition to removing organic compounds, the exposed copper surfaces are consistently oxidized, thereby passivating the surface areas of the copper and substantially avoiding any pitting corrosion of the copper. In one particular embodiment, a hydrogen peroxide solution with approximately 0.5-5.0 weight percent of hydrogen peroxide in de-ionized water is supplied to the polishing pad 202.

A treatment in the range of approximately 10-30 seconds upon application of the hydrogen peroxide solution ensures a substantially complete oxidation of exposed copper areas, such as the surface areas of the trenches 105, 103 of the structure 100. In another embodiment, a downforce applied to the substrate 240 during rinsing of the substrate with the hydrogen peroxide solution is lowered compared to the downforce applied during the polish sequence. Typically, a downforce applied to the substrate 240 during rinsing is in the range of approximately 100-1000 Newton. After completion of the rinse cycle, the substrate 240 is removed from the CMP station 200 and is dried so that the substrate 240 may be released for further processes, such as the deposition of further material layers. Due to the substantially completely oxidized copper surface portions, pitting corrosion may be substantially avoided and the efficiency of subsequent dry clean processes required for providing a substantially pure copper surface is significantly increased as a continuous copper oxide layer may be removed more reliably than localized pitting corrosion areas. Thus, device reliability may significantly be improved in that conductivity degradation of the copper lines and delamination of subsequently deposited material layers is reduced.

In other embodiments, a separate rinse station (not shown) may be provided and the substrate 240 is subjected to a rinse treatment after completion of the CMP cycle. Again, the rinse treatment, either totally or partially, is carried out with an oxidizing agent to remove organic contaminants and to oxidize the copper surface. Preferably, the oxidizing agent is applied during the final phase of the rinse treatment. In other embodiments, however, the oxidizing agent may be added at an initial and/or an intermediate phase of the rinse treatment, as long as it is ensured that the exposed copper surface areas are substantially completely oxidized. For example, after the end point of the chemical mechanical polishing is indicated, a hydrogen peroxide solution may be provided to the polishing pad of the respective CMP unit, for example the unit 220, so that immediately after polishing the substrate 240, a rinse treatment is carried out to remove particles, organic contaminants and to oxidize the copper surface areas. After 10-30 seconds, the rinse treatment may be continued on a different CMP unit or in a separate rinse station or a wet clean station, wherein the now passivated oxidized copper surface allows the employment of a neutral rinse solution, such as ultra pure water, to further remove particles, and the like.

In other embodiments, the pH value of the rinse solution containing hydrogen peroxide is adjusted to approximately 4 or higher to promote the formation of a highly passivating copper oxide film on exposed copper surface areas. In one embodiment, it may be preferable, in view of reducing process time, to provide the rinse solution with an elevated temperature in the range of approximately 40-65° C. Thus, a rinse time of approximately 5-15 seconds may be sufficient to substantially completely oxidize the exposed copper surface areas. Particle removal and further rinsing may be carried out prior to and/or after the rinsing with an oxidizing agent in accordance with process requirements.

As a result, the present invention allows the effective removal of organic compounds that may conventionally lead to copper contamination in subsequent deposition processes, while, at the same time, the exposed copper surface areas are oxidized. By providing a substantially completely oxidized copper surface, subsequent deposition sequences requiring preceding clean processes for providing a pure copper surface may, therefore, be carried out in a more efficient and reliable manner. Thus, device performance and reliability are profoundly increased.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A method of planarizing a copper-containing surface of a substrate, the method comprising:
chemically mechanically polishing the surface to remove excess copper; and
rinsing the substrate with an oxidizing agent to oxidize exposed copper areas.

2. The method of claim 1, wherein said oxidizing agent is hydrogen peroxide.

3. The method of claim 2, wherein said hydrogen peroxide is provided in a solution with a concentration of approximately 0.5-5.0 weight percent.

4. The method of claim 1, wherein said rinsing is carried out on a CMP station with a downforce in the range of approximately 100-1000 Newton.

5. The method of claim 1, wherein said rinsing of the substrate is carried out as a final wet-treatment step.

6. The method of claim 1, wherein said rinsing with an oxidizing agent is carried out as an intermediate phase of a rinsing sequence.

7. The method of claim 1, wherein rinsing said substrate with an oxidizing agent is carried out for a time period of approximately 5-30 seconds.

8. The method of claim 1, wherein rinsing said substrate with an oxidizing agent includes providing said oxidizing agent at an elevated temperature of approximately 40-65° C.

9. A method of planarizing a metal-containing surface of a substrate, the method comprising:
chemical mechanical polishing the surface to remove excess metal; and
carrying out a clean sequence including:
a first step of rinsing the substrate; and
a last step of rinsing the substrate with an oxidizing agent to oxidize exposed areas of the metal.

10. The method of claim 9, wherein said oxidizing agent is hydrogen peroxide.

11. The method of claim 10, wherein said hydrogen peroxide is provided in a solution with a concentration of approximately 0.5-5.0 weight percent.

12. The method of claim 9, wherein said rinsing is carried out on a CMP station with a downforce in the range of approximately 100-1000 Newton.

13. The method of claim 9, wherein said rinsing of the substrate is carried out as a final wet-treatment step.

14. The method of claim 9, wherein rinsing said substrate with an oxidizing agent is carried out for a time period of approximately 5-30 seconds.

15. The method of claim 9, wherein rinsing said substrate with an oxidizing agent includes providing said oxidizing agent at an elevated temperature of approximately 40-65° C.

16. A method of minimizing corrosion of an exposed copper region after a wet surface treatment of a copper-containing substrate, the method comprising:
performing a wet-treatment process on the substrate; and
rinsing the substrate with an oxidizing agent as a final wet-treatment step.

17. The method of claim 16, wherein said wet-treatment includes the chemical mechanical polishing of the substrate.

18. The method of claim 16, wherein said oxidizing agent is hydrogen peroxide.

19. The method of claim 18, wherein said hydrogen peroxide is provided in a solution with a concentration of approximately 0.5-5.0 weight percent.

20. The method of claim 16, wherein said rinsing is carried out on a CMP station with a downforce in the range of approximately 100-1000 Newton.

21. The method of claim 16, wherein said rinsing of the substrate is carried out as a final wet-treatment step.

22. The method of claim 16, wherein said rinsing with an oxidizing agent is carried out as an intermediate phase of a rinsing sequence.

23. The method of claim 16, wherein rinsing said substrate with an oxidizing agent is carried out for a time period of approximately 5-30 seconds.

24. The method of claim 16, wherein rinsing said substrate with an oxidizing agent includes providing said oxidizing agent at an elevated temperature of approximately 40-65° C.
